(19) United States
(12) Patent Application Publication
(10) Pub. No.: US 2013/0082302 A1
(43) Pub. Date: Apr. 4, 2013

(54) SEMICONDUCTOR DEVICE

(71) Applicants: Kazutoshi NAKAMURA, Kanagawa-ken (JP); Tsuneo Ogura, Kanagawa-ken (JP)

(72) Inventors: Kazutoshi NAKAMURA, Kanagawa-ken (JP); Tsuneo Ogura, Kanagawa-ken (JP)

(73) Assignee: Kabushiki Kaisha Toshiba, Tokyo (JP)

(21) Appl. No.: 13/612,447

(22) Filed: Sep. 12, 2012

(30) Foreign Application Priority Data
Sep. 29, 2011 (JP) P2011-215727
Jul. 11, 2012 (JP) 2012-155994

(51) Int. Cl. H01L 29/739

(52) U.S. Cl. 257/155; 257/E29.201

(57) ABSTRACT

A semiconductor device comprises: a substrate having a first and second surface; trenches provided on the second surface; a gate electrode provided in each trench; a first-conductive-type emitter layer provided on the second surface and contacting with the trenches; and an emitter electrode provided on the second surface to extend in a longitudinal direction of the trenches, the emitter electrode having a non-contact portion partially provided in the first-conductive-type emitter layer.

### CROSS-REFERENCE TO RELATED APPLICATION

This application is based upon and claims the benefit of priority from the prior Japanese Patent Applications No. 2011-215727, filed Sep. 29, 2011, and No. 2012-155994, filed Jul. 11, 2012 the entire contents of which are incorporated herein by references.

### FIELD

Embodiments described herein relate generally to a semiconductor device.

### BACKGROUND

Insulated gate bipolar transistors (IGBTs) have been used widely as power semiconductor elements having high breakdown voltage in recent years. One of methods for reducing an on-voltage of such an IGBT is to increase the mutual inductance of a MOS portion. Specifically, this method is to increase a channel width, or in other words, to increase a width of an emitter layer. However, the increase in the width of the emitter layer leads to reduction of a reverse bias safe operation area and a short-circuit capacity.

An example of related art includes Patent Reference of JP-A-2008-244466.

### DESCRIPTION OF THE DRAWINGS

FIG. 1 is a plan view showing a semiconductor device of a first embodiment.

FIG. 2 is a cross-sectional view showing a cross section taken along the A-A′ line in FIG. 1.

FIG. 3 is a cross-sectional view showing a cross section taken along the B-B′ line in FIG. 1.

FIG. 4 is a cross-sectional view showing a cross section taken along the C-C′ line in FIG. 1.

FIG. 5 is a cross-sectional view showing a cross section taken along the D-D′ line in FIG. 1.

FIG. 6 is a plan view of a semiconductor device showing comparative example 1.

FIG. 7 is a cross-sectional view showing a cross section taken along the E-E′ line in FIG. 6.

FIG. 8 is a plan view of a semiconductor device showing comparative example 2.

FIG. 9A is a comparison graph of a collector-emitter voltage (V_{ce}) with a collector-emitter current (I_{ce}) in terms of comparative example 1 and comparative example 2.

FIG. 9B is an enlarged view of a low V_{ce} section in FIG. 9A.

FIG. 10A is a graph showing a simulation result of comparison of a collector-emitter voltage (V_{ce}) with a collector-emitter current (I_{ce}) in terms of the first embodiment and comparative example 2.

FIG. 10B is an enlarged view of a low V_{ce} section in FIG. 10A.

FIG. 11 is a plan view showing a semiconductor device of a second embodiment.

FIG. 12 is a cross-sectional view showing a cross section taken along the F-F′ line in FIG. 11.

FIG. 13A to FIG. 13F are cross-sectional views taken along the G-G′ line in FIG. 11, showing a sequence of processes.

FIG. 14A to FIG. 14F are cross-sectional views taken along the H-H′ line in FIG. 11, showing the sequence of processes.

FIG. 15A to FIG. 15F are cross-sectional views taken along the I-I′ line in FIG. 11, showing the sequence of processes.

FIG. 16 is a plan view showing a semiconductor device of a third embodiment.

FIG. 17 is a cross-sectional view showing a cross section taken along the J-J′ line in FIG. 16.

FIG. 18 is a cross-sectional view showing a cross section taken along the K-K′ line in FIG. 16.

FIG. 19 is a cross-sectional view showing a cross section taken along the L-L′ line in FIG. 16.

### DETAILED DESCRIPTION

In general, according to one embodiment, a semiconductor device comprises: a first-conductive-type base layer provided in a substrate having first and second surfaces; a second-conductive-type collector layer provided on the first surface; a collector electrode provided on the second-conductive-type collector layer; a second-conductive-type base layer provided on the second surface; a second-conductive-type contact layer selectively provided on the second-conductive-type base layer; trenches provided on the second surface; a gate electrode provided in each trench via a gate insulating film; a first-conductive-type emitter layer provided on the second surface and contacting with the trenches; an insulating film provided on the gate electrodes; and an emitter electrode provided on the second surface to extend in a longitudinal direction of the trenches, the emitter electrode having a non-contact portion partially provided in the first-conductive-type emitter layer.

In general, according to one embodiment, a semiconductor device comprises: a first-conductive-type base layer provided in a substrate having first and second surfaces; a second-conductive-type collector layer provided on the first surface; a collector electrode provided on the second-conductive-type collector layer; a second-conductive-type base layer provided on the second surface; a second-conductive-type contact layer selectively provided on the second-conductive-type base layer; trenches provided on the second surface; a gate electrode provided in each trench via a gate insulating film; a first-conductive-type emitter layer provided on the second surface and contact with the trenches; an insulating film provided on the gate electrodes; and an emitter electrode provided on the second surface to extend in a longitudinal direction of the trenches, the emitter electrode having a portion in ohmic contact and a portion in Schottky contact with the first-conductive-type emitter layer.

Embodiments of the invention will be described below with reference to the accompanying drawings. The embodiments will be described on the premise that a first conductive type is a negative type (N-type) and a second conductive type is a positive type (P-type). It is to be noted, however, that the invention can also be embodied when the first conductive type is the P-type and the second conductive type is the N-type.

### First Embodiment

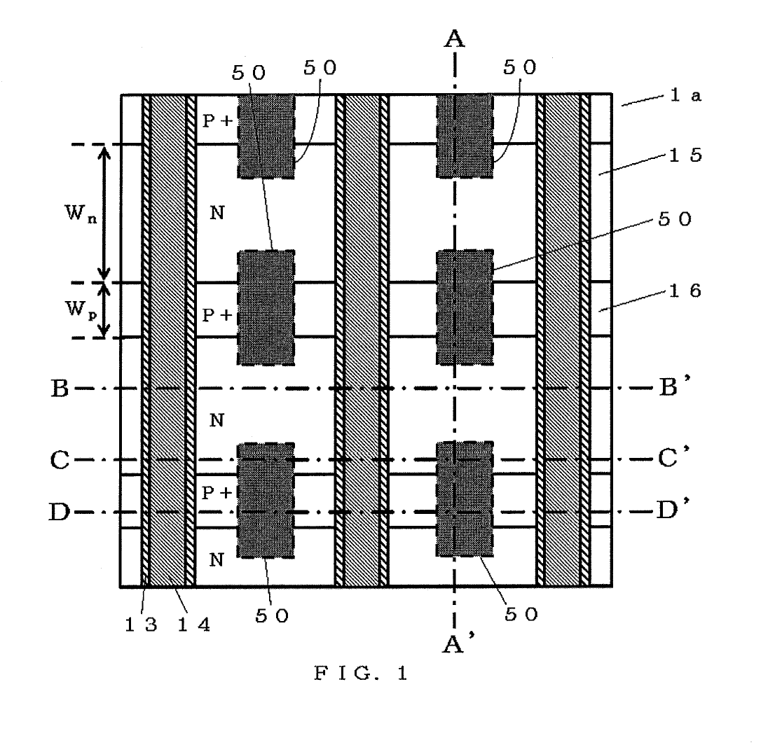

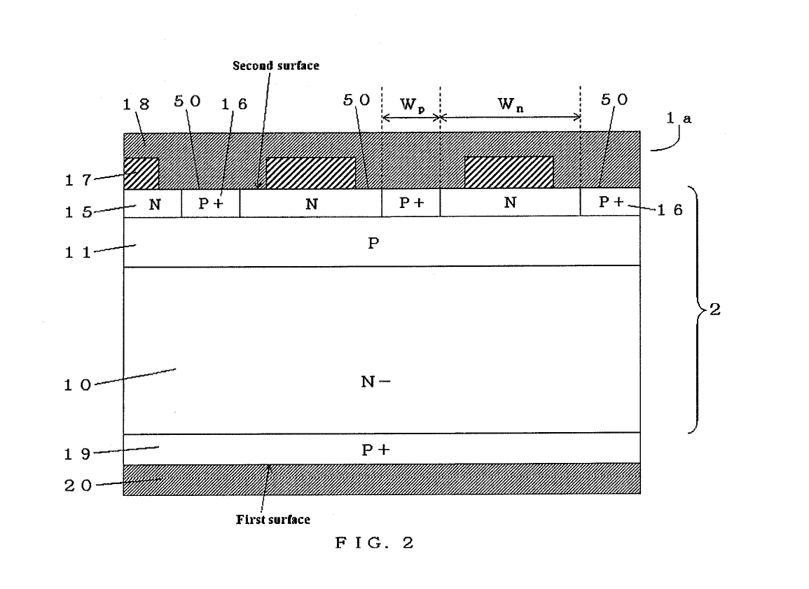

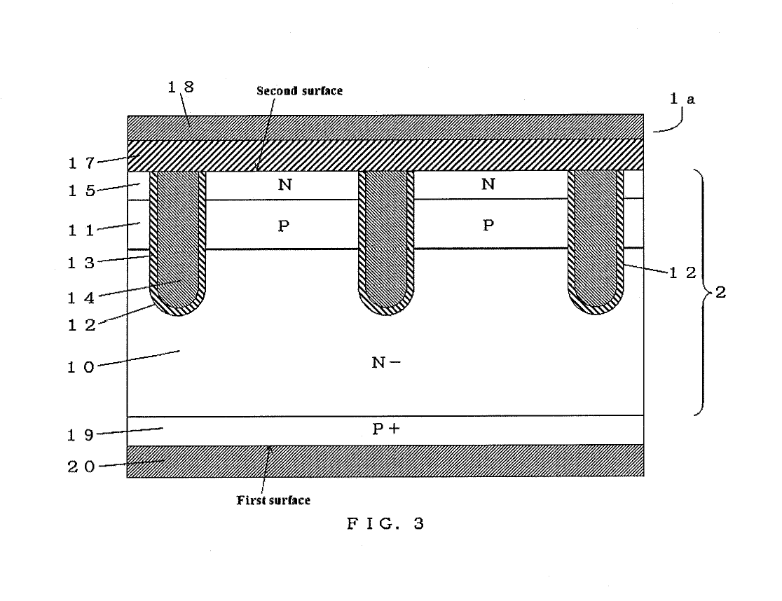

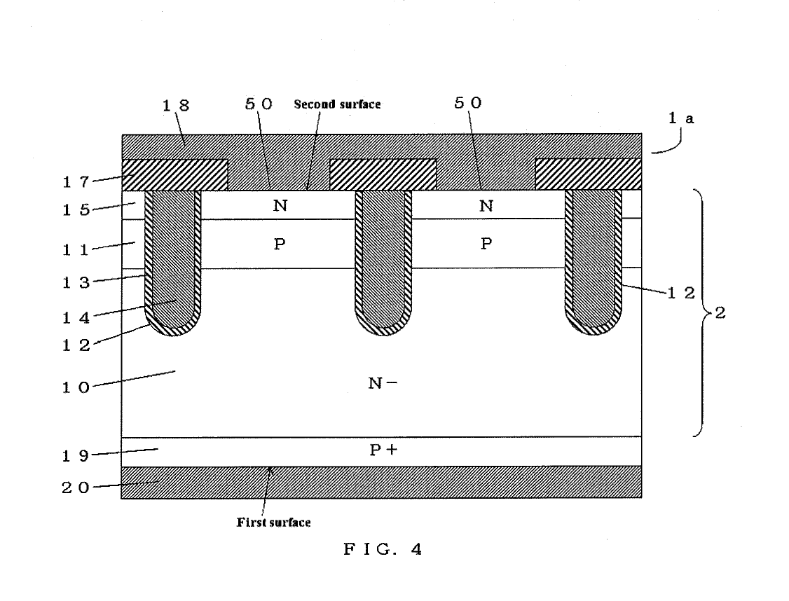

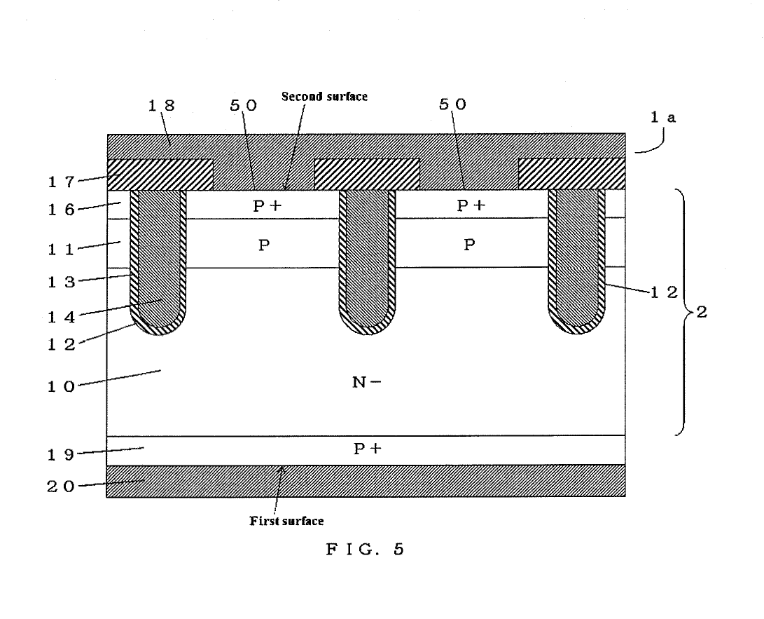

FIG. 1 is a plan view showing a structure of a semiconductor device 1 of a first embodiment. FIG. 2 is a cross-sectional view showing a cross section taken along the A-A′ line in FIG. 1. FIG. 3 is a cross-sectional view showing a cross section taken along the B-B′ line in FIG. 1. FIG. 4 is a cross-sectional view showing a cross section taken along the C-C′ line in FIG. 1. FIG. 5 is a cross-sectional view showing a cross section taken along the D-D′ line in FIG. 1. Illustration of an insulating film 17 and an emitter electrode 18 is omitted in FIG. 1.

As shown in FIG. 1 to FIG. 5, the semiconductor device 1 of this embodiment has an IGBT structure. To obtain the structure, an N⁻-type base layer 10 is first provided in a substrate 2 having first and second surfaces. Then, a P-type base layer 11 is provided on the second surface side and in contact with the N⁻-type base layer 10.

Multiple trenches 12 are provided at given intervals and in parallel with each other to extend from a surface of the P-type base layer 11 to the inside of the N⁻-type base layer 10. A gate electrode 14 is buried in each of the trenches 12 with a gate insulating film 13 interposed in between. Polycrystalline silicon is used as the gate electrode 14, for example.

Then, an N-type emitter layer 15 and a P⁺-type contact layer 16 are provided on the second surface side in such a manner as to contact with the P-type base layer 11. Meanwhile, the N-type emitter layer 15 and the P⁺-type contact layer 16 are provided in contact with side surfaces of the trenches 12 and alternately in a longitudinal direction of the trenches 12. Here, a surface impurity concentration of the N-type emitter layer 15 is adjusted to a lower concentration (about 1×10¹⁸ to about 5×10¹⁹ cm⁻³) than a surface impurity concentration (in excess of about 5×10¹⁹ cm⁻³) of a conventional N⁺-type emitter layer 21. In addition, a ratio Wₙ/Wₚ between a width Wₙ of the N-type emitter layer 15 in the longitudinal direction of the trenches 12 and a width Wₚ of the P⁺-type contact layer 16 in the same direction is set equal to or more 0.6 or preferably equal to or more 1. A width ratio between the conventional N⁺-type emitter layer 21 and the P⁺-type contact layer 16 is set equal to or less 0.4 in light of a short-circuit capacity.

Moreover, an insulating film 17 is provided on an upper portion of the gate electrodes 14. In addition, an emitter electrode 18 is provided on the N-type emitter layer 15, the P⁺-type contact layer 16, and the insulating film 17. The N-type emitter layer 15 and the P⁺-type contact layer 16 contact with the emitter electrode 18 in contact regions 50. Here, the contact regions 50 are provided parallel to the longitudinal direction of the trenches 12.

In this embodiment, as shown in FIG. 1 and FIG. 2, a non-contact portion is formed by partially reducing a portion of contact between the N-type emitter layer 15 and the emitter electrode 18 with formation of the insulating film 17. Although the non-contact portion is formed by partially reducing the portion of contact with formation of the insulating film 17 in this embodiment, the non-contact portion may be formed instead by not providing the emitter electrode 18 on a part of the N-type emitter layer 15, for example.

Further, a P⁺-type collector layer 19 is provided on the first surface side of the N⁻-type base layer 10 and a collector electrode 20 is provided on a surface thereof.

In the semiconductor device 1 having the IGBT structure formed as described above, the N-type emitter layer 15 formed along the trenches 12, the P-type base layer 11, and the N⁻-type base layer 10 collectively constitute an N-channel-type MOS transistor as shown in FIG. 4.

Meanwhile, as shown in FIG. 5, the P⁺-type contact layer 16, the P-type base layer 11, the N⁻-type base layer 10, and the P⁺-type collector layer 19 collectively constitute a PNP bipolar transistor. The semiconductor device 1 is operated by combined actions of the MOS transistor and the PNP bipolar transistor.

For example, a voltage higher than a threshold voltage is applied between the gate electrode 14 and the emitter electrode 18 while applying a positive potential to the collector electrode 20. In this case, an inversion layer is formed on a surface of the P-type base layer 11 in contact with the gate insulating film 13 (the trench 12). Thus, the MOS transistor becomes an on-state and an electronic current flows through the MOS transistor.

The electronic current flows from the collector electrode 20 to the emitter electrode 18 via the P⁺-type collector layer 20, the N⁻-type base layer 10, the N-type inversion layer formed on the surface of the P-type base layer 11 in contact with the gate insulating film 13 (the trench 12) i.e. a channel of the MOS transistor, and the N-type emitter layer 15.

The electronic current functions as a base current of the above-described PNP transistor. Specifically, when the electronic current flows, the PNP transistor becomes in an on-state whereby a hole current flows through the PNP transistor. The hole current flows from the collector electrode 20 to the emitter electrode 18 via the P⁺-type collector layer 20, the N⁻-type base layer 10, the P-type base layer 11, and the P⁺-type contact layer 16.

As described above, in the semiconductor device 1, when the electronic current flows through the MOS transistor, the base current is supplied to the PNP transistor and the PNP transistor thereby becomes in an on-state. Accordingly, the PNP transistor is switched between on-state and off-state as the MOS transistor is switched between on-state and off-state by controlling the voltage on the gate electrode 14.

When the N-type emitter layers 15 and the P⁺-type contact layers 16 are alternately provided in contact with the side surfaces of the trenches 12 and in the longitudinal direction of the trenches 12 as described in this embodiment, an on-voltage can be reduced by setting the ratio Wₙ/Wₚ between the width Wₙ of each N-type emitter layer 15 and the width Wₚ of each P⁺-type contact layer 16 equal to or more 0.6 or preferably equal to or more 1.

Nevertheless, while the on-voltage can be reduced by setting the ratio Wₙ/Wₚ equal to or more 0.6, a problem of reduction in the short-circuit capacity arises due to an increase in a saturated current value. Moreover, if the ratio Wₙ/Wₚ is too large, there is another problem of reduction in a reverse bias safe operation area (RBSOA) because the semiconductor device 1 is likely to cause latch-up by an action of a parasitic NPN transistor upon an increase in current density.

In this embodiment, such an action of the NPN transistor is suppressed by providing the N-type emitter layer 15 with a lower surface impurity concentration than that of the conventional layer. Thus, it is possible to avoid reduction in the RBSOA which may occur in association with the increase in the ratio Wₙ/Wₚ.

Meanwhile, the non-contact portion is provided by partially reducing the portion of contact between the N-type emitter layer 15 and the emitter electrode 18 with formation of the insulating film 17. As a consequence, there is the region where the electronic current passes through a parasitic resistance inside the N-type emitter layer 15 and flows from the N-type channel formed on the surface in contact with the gate insulating film 13 (the trench 12) to the N⁻-type base layer 10 in the on-state. Here, the parasitic resistance inside the N-type emitter layer 15 occurs because the impurity concentration of the N-type emitter layer 15 is set low.

Due to the presence of the parasitic resistance inside the N-type emitter layer 15, as the current density becomes high, the electric potential of the emitter is increased by a voltage drop and a threshold is raised by a back bias effect, thereby pinching off the channel. In this way, the amount of the electronic current can be controlled. As a consequence, it is possible to suppress an increase in the saturated current value and to avoid reduction in the short-circuit capacity.

On the other hand, the channel is not pinched off in a position where the current density is low. Thus, the on-voltage can be reduced by using an effect of a wider channel width obtained by setting the ratio Wₙ/Wₚ greater than the conventional configuration, i.e., by setting the channel width larger than the conventional configuration.

In addition, the location allowing the hole current to flow is reduced by setting the ratio Wₙ/Wₚ greater than the conventional configuration, i.e., by increasing the area of the N-type emitter layer 15 relative to the P⁺-type contact layer 16 in a plan view as shown in FIG. 1. As a result, an effect of an increase in the hole density at the surface of the P⁺-type contact layer 16 is also expected by an injection enhancement effect (IE effect).

As described above, the semiconductor device 1 of this embodiment can reduce the on-voltage and ensure the short-circuit capacity at the same time by setting the ratio Wₙ/Wₚ between the width Wₙ of the N-type emitter layer 15 having a lower surface impurity concentration than the conventional layer and the width Wₚ of the P⁺-type contact layer 16 equal to or more 0.6 or preferably equal to or more 1, and by providing the non-contact portion by partially reducing the portion of contact between the N-type emitter layer 15 and the emitter electrode 18 with formation of the insulating film 17.

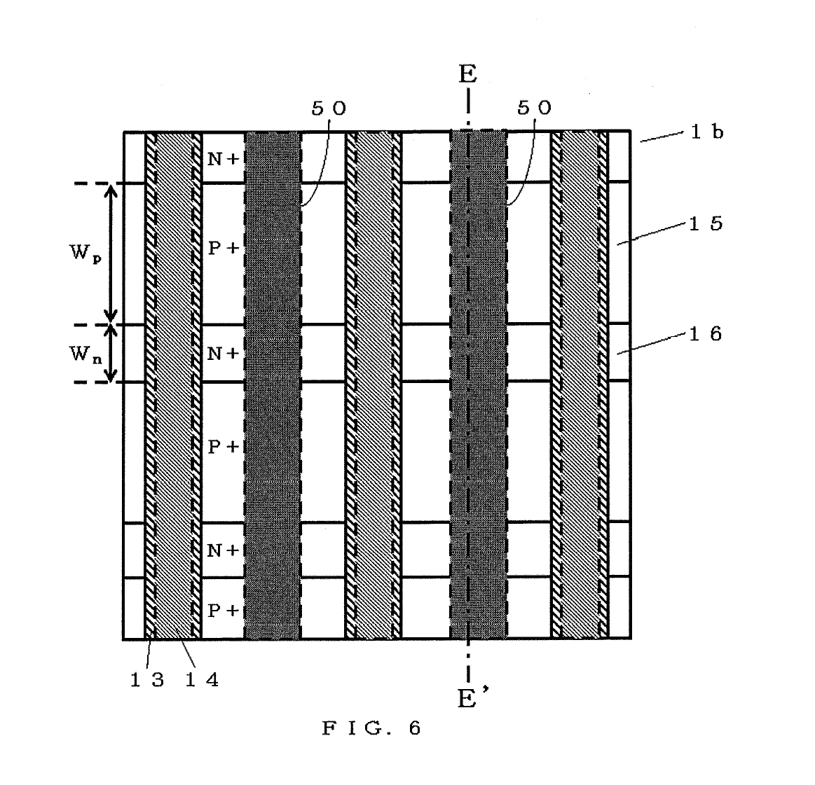

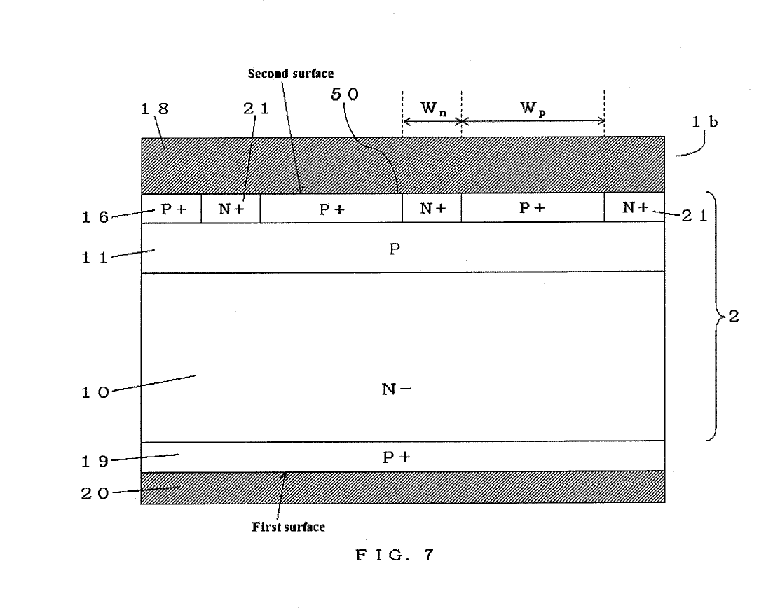

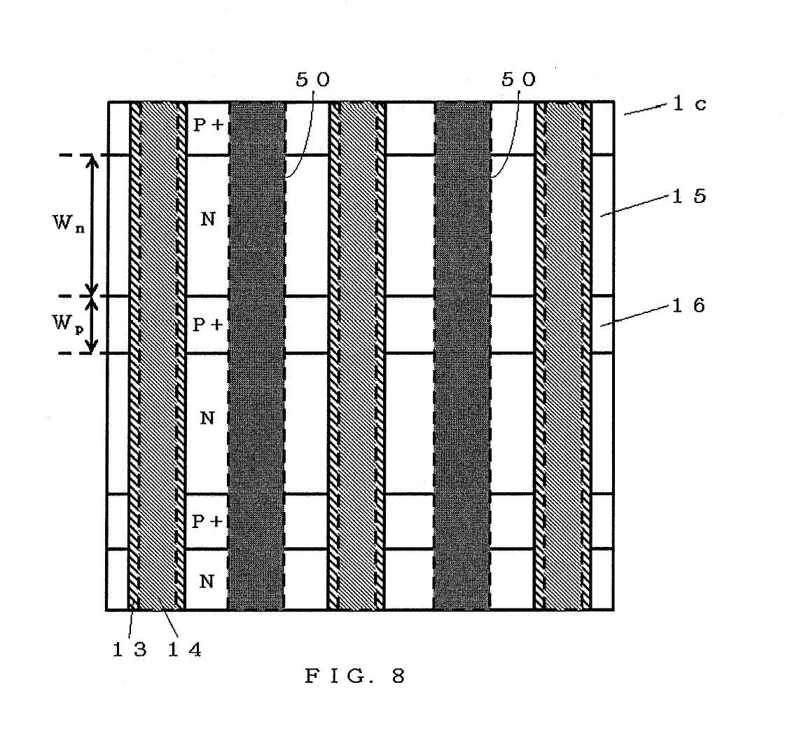

Here, a semiconductor device 1 having a conventional IGBT structure is shown as a comparative example of the first embodiment. FIG. 6 is a plan view of the semiconductor device 1 showing comparative example 1. FIG. 7 is a cross-sectional view showing a cross section taken along the E-E′ line in FIG. 6. Meanwhile, FIG. 8 is a plan view of a semiconductor device showing comparative example 2. Illustration of the insulating film 17 and the emitter electrode 18 is omitted in FIGS. 6 and 8. It is to be also noted that the constituents in these comparative examples which are the same as the constituents of the semiconductor device 1 of the first embodiment shown in FIG. 1 and FIG. 2 will be denoted by the same reference numerals.

As shown in FIG. 6 and FIG. 7, comparative example 1 includes the N⁺-type emitter layer 21 having the high surface impurity concentration (equal to or more about 5×10¹⁹ cm⁻³). This is the example of setting the ratio Wₙ/Wₚ between the width Wₙ of the N⁺-type emitter layer 21 and the width Wₚ of the P⁺-type contact layer 16 equal to or less 0.4 and not partially reducing a portion of contact between the N⁺-type emitter layer 21 and the emitter electrode 18 with formation of the insulating film 17. The conventional IGBT has the above-described structure.

A conceivable option to reduce the on-voltage in comparative example 1 having the above-described configuration is to set the ratio Wₙ/Wₚ greater than 0.4.

As shown in FIG. 8, comparative example 2 includes the N-type emitter layer 15 having a lower surface impurity concentration than the N⁺-type emitter layer 21. In addition, the ratio Wₙ/Wₚ is set greater than 0.4.

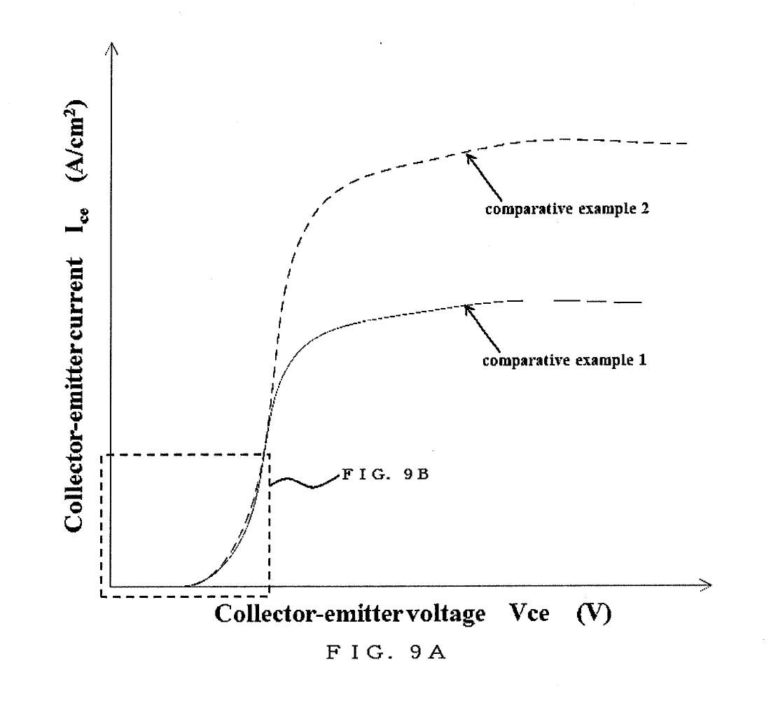

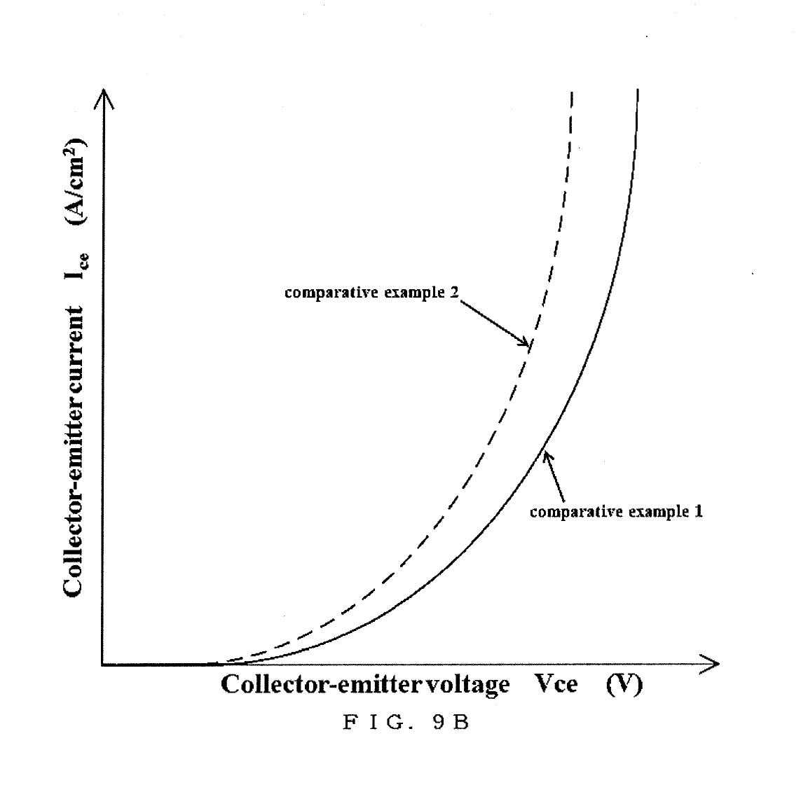

FIG. 9A shows a comparison graph of a collector-emitter voltage (V_{ce}) with a collector-emitter current (I_{ce}) in terms of comparative example 1 and comparative example 2, while FIG. 9B shows an enlarged view of a low V_{ce} section in the graph of FIG. 9A. In FIGS. 9A and 9B, a solid line shows a pattern of comparative example 1 while a broken line shows a pattern of comparative example 2.

In the case of comparative example 2, the amount of electron injection and a hole discharge resistance are increased due to an effect of setting the ratio Wₙ/Wₚ greater than 0.4. As a result, comparative example 2 tends to reduce an on-resistance as shown in FIG. 9B.

However, setting the ratio Wₙ/Wₚ too large leads to the two problems of reduction in the short-circuit capacity and the RBSOA as described previously.

Concerning these problems, it is possible to control the action of the NPN transistor that causes reduction in the RBSOA by providing the N-type emitter layer 15 having the low surface impurity concentration as described in comparative example 2. However, as shown in FIG. 9A, the saturated current value tends to be increased as a consequence of setting the ratio Wₙ/Wₚ greater than 0.4. Accordingly, in the case where the portion of contact between the N⁺-type emitter layer 21 and the emitter electrode 18 is not partially reduced with formation of the insulating film 17 as in comparative example 2, the short-circuit capacity is reduced in return for reduction in the on-resistance.

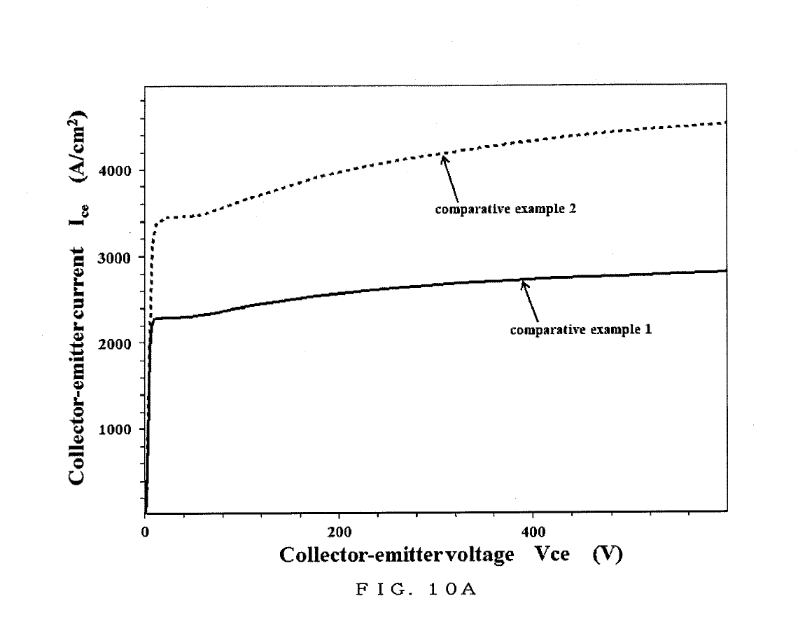

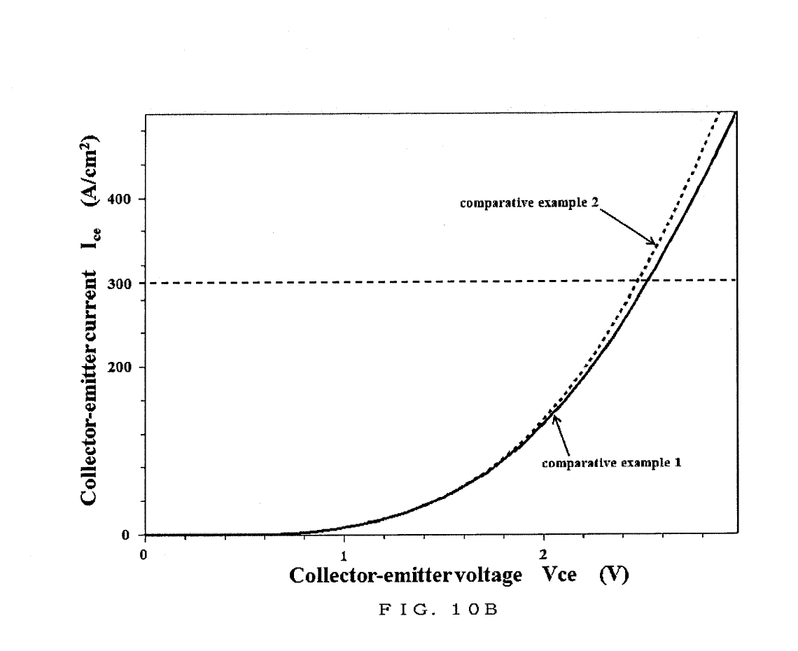

FIG. 10A is a graph showing a simulation result of comparison of a collector-emitter voltage (V_{ce}) with a collector-emitter current (I_{ce}) in terms of the first embodiment and comparative example 2, and FIG. 10B shows an enlarged view of a low V_{ce} section in FIG. 10A.

Here, conditions of the simulation are as follows. The width Wₙ of the N-type emitter layer 15 is set to 10 μm. The width Wₚ of the P⁺-type contact layer 16 is set to 4.5 μm. An ohmic contact width between the N-type emitter layer 15 and the emitter electrode 18 in the first embodiment is set to 1.0 μm. An effective area is set to 1.0 cm². The surface impurity concentration of the N-type emitter layer 15 is set to 5.0×10¹⁷ cm⁻³. Lastly, a gate voltage value is set to 15 V.

As shown in FIG. 10B, when the on-voltages between the first embodiment and comparative example 2 are compared with each other at the collector-emitter current value I_{ce} of 300 A/cm², the on-voltage in comparative example 2 is lower than the on-voltage in the first embodiment by about 50 mV because the portion of contact between the N⁺-type emitter layer 21 and the emitter electrode 18 is not partially reduced with formation of the insulating film 17 in comparative example 2.

However, regarding comparison of the saturated current values, the saturated current value of the first embodiment, which includes the non-contact portion provided by partially reducing the portion of contact between the N-type emitter layer 15 and the emitter electrode 18 with formation of the insulating film 17, is reduced about 0.62 times as much as the saturated current value in comparative example 2 as shown in FIG. 10A. Thus, an improvement in the saturated current value can be confirmed. As a consequence, the first embodiment can retain more short-circuit capacity than comparative example 2.

From the aspects mentioned above, the first embodiment can realize reduction in the on-voltage by setting the ratio Wₙ/Wₚ between the width Wₙ of the N-type emitter layer 15 in the longitudinal direction of the trenches 12 and the width Wₚ of the P⁺-type contact layer 16 in the same direction equal to or more 0.6 or preferably equal to or more 1. At the same time, the first embodiment can suppress reduction in the RBSOA and in the short-circuit capacity, which may possibly occur in the increase of the more ratio, by setting the low impurity concentration of the N-type emitter layer 15 and providing the non-contact portion by partially reducing the portion of contact between the N-type emitter layer 15 and the emitter electrode 18 with formation of the insulating film 17.

### Second Embodiment

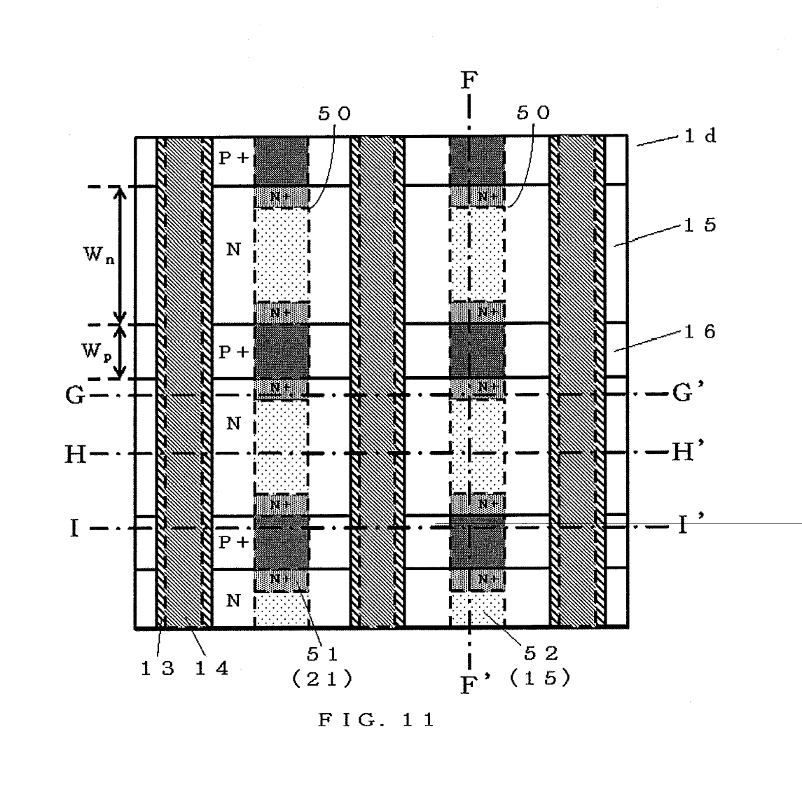

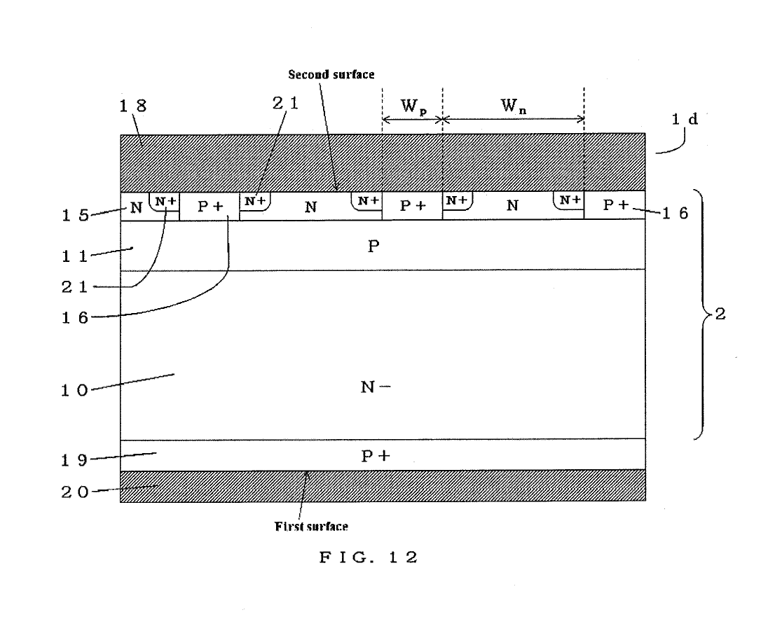

FIG. 11 is a plan view showing a structure of a semiconductor device 1 of a second embodiment, and FIG. 12 is a cross-sectional view showing a cross section taken along the F-F′ line in FIG. 11. Here, illustration of the insulating film 17 and the emitter electrode 18 is omitted in FIG. 11. It is to be also noted that the constituents in the second embodiment which are the same as the constituents of the semiconductor device 1 of the first embodiment shown in FIG. 1 and FIG. 2 will be denoted by the same reference numerals.

The semiconductor device 1 of the second embodiment is different from the semiconductor device of the first embodiment in that the portion of contact between the N-type emitter layer 15 and the emitter electrode 18 is not partially reduced with formation of the insulating film 17. Instead, the N⁻-type emitter layer 21 having the high surface impurity concentration is formed selectively in the N-type emitter layer 15. In this way, ohmic contact regions 51 (having an N-type surface impurity concentration equal to or more about 1×10¹⁹ cm⁻³) and Schottky contact regions 52 (having an N-type surface impurity concentration less about 1×10¹⁹ cm⁻³ or preferably in a range from about 1×10¹⁶ to 5×10¹⁸ cm⁻³) are provided at portions of contact with the emitter electrode 18.

In the second embodiment as well, the ratio Wₙ/Wₚ between the width Wₙ of the N-type emitter layer 15 in the longitudinal direction of the trenches 12 and the width Wₚ of the P⁺-type contact layer 16 in the same direction is set greater than the ratio Wₙ/Wₚ in the conventional IGBT structure shown in comparative example 1. Thus, the second embodiment can also reduce the on-voltage.

Moreover, since the ohmic contact regions 51 (regions of contact between the N⁺-type emitter layer 21 and the emitter electrode 18) and the Schottky contact regions 52 (regions of contact between the N-type emitter layer 15 and the emitter electrode 18) are selectively provided, there is the region similarly to the first embodiment where the electronic current passes through the parasitic resistance inside the N-type emitter layer 15 and flows from the N-type channel formed on the surface in contact with the gate insulating film 13 (the trench 12) to the N⁻-type base layer 10 when the semiconductor device 1 is in on-state.

Due to the presence of the parasitic resistance, as the current density becomes high, the electric potential of the emitter is increased by a voltage drop and the threshold is raised by the back bias effect, thereby pinching off the channel. In this way, the amount of the electronic current can be controlled. As a consequence, it is possible to suppress an increase in the saturated current value and to avoid reduction in the short-circuit capacity as similar to the first embodiment.

Accordingly, when the ohmic contact regions 51 (the regions of contact between the N⁺-type emitter layer 21 and the emitter electrode 18) and the Schottky contact regions 52 (the regions of contact between the N-type emitter layer 15 and the emitter electrode 18) are selectively provided as described in the second embodiment, it is possible to reduce the on-voltage and to suppress reduction in the RBSOA and in the short-circuit capacity at the same time as similar to the case (the first embodiment) of partially reducing the portion of contact between the N-type emitter layer 15 and the emitter electrode 18 with formation of the insulating film 17.

In the first embodiment, in order to realize the ohmic contact, it is difficult to sufficiently reduce the surface impurity concentration of the N-type emitter layer 15. In general, the parasitic NPN transistor tends to be more active as the surface impurity concentration of the N-type emitter layer 15 becomes higher. However, the surface impurity concentration of the N-type emitter layer 15 can be sufficiently reduced by providing the ohmic contact regions 51 and the Schottky contact regions 52 as described in the second embodiment. Thus, the second embodiment realizes the ohmic contact by using the N⁺-type emitter layer 21 while suppressing the electron injection from the N-type emitter layer in the parasitic NPN transistor.

Another advantageous effect is that, unlike the first embodiment, it is not necessary to perform delicate processing on the insulating film 17 at the portions of contact (the contact regions 50) with the emitter electrode 18.

Here, methods of selectively providing the N⁺-type emitter layer 21 in the N-type emitter layer 15 having the low surface impurity concentration as described in the second embodiment include an ordinary formation method that involves arsenic (As) or phosphorous (P) implantation as well as thermal diffusion, and a method that involves arsenic segregation using nitrogen silicide (NiSi) or sulfur (S) doping, for example. By applying the method involving As segregation using nitrogen silicide (NiSi) or S doping, the impurity concentration on the surface of the N⁺-type emitter layer 21 can be increased locally and, at the same time, the electron injection from the N⁺-type emitter layer 21 in the parasitic NPN transistor can also be suppressed.

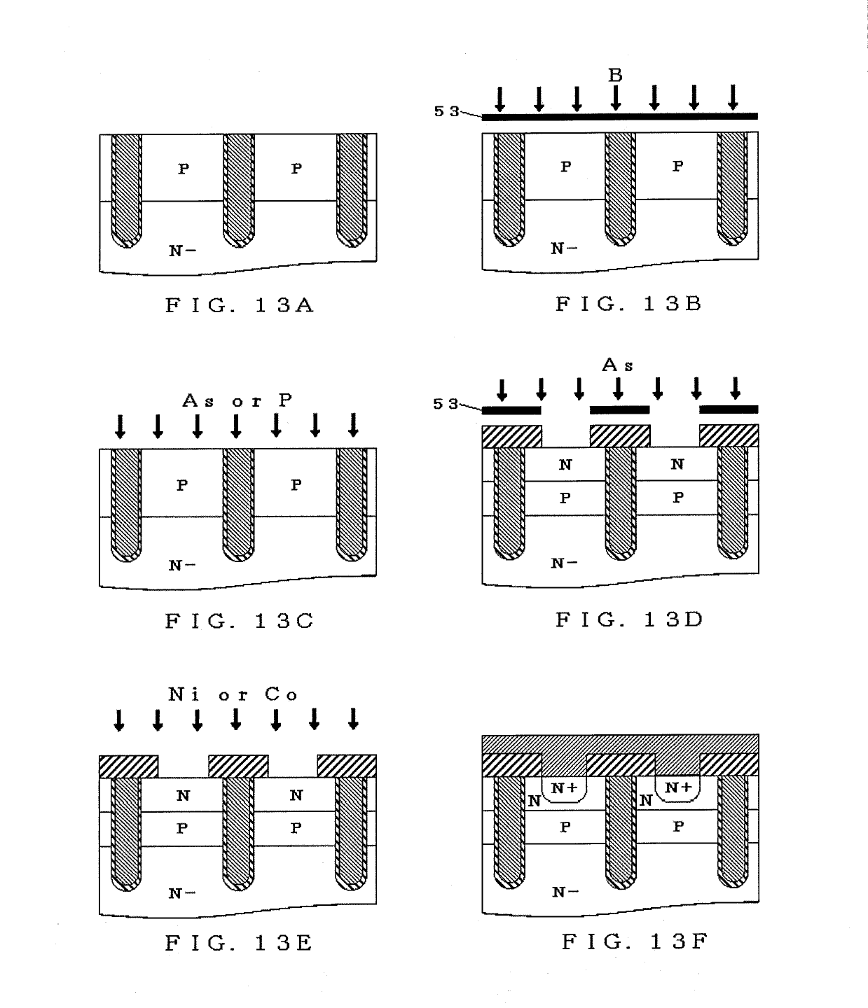

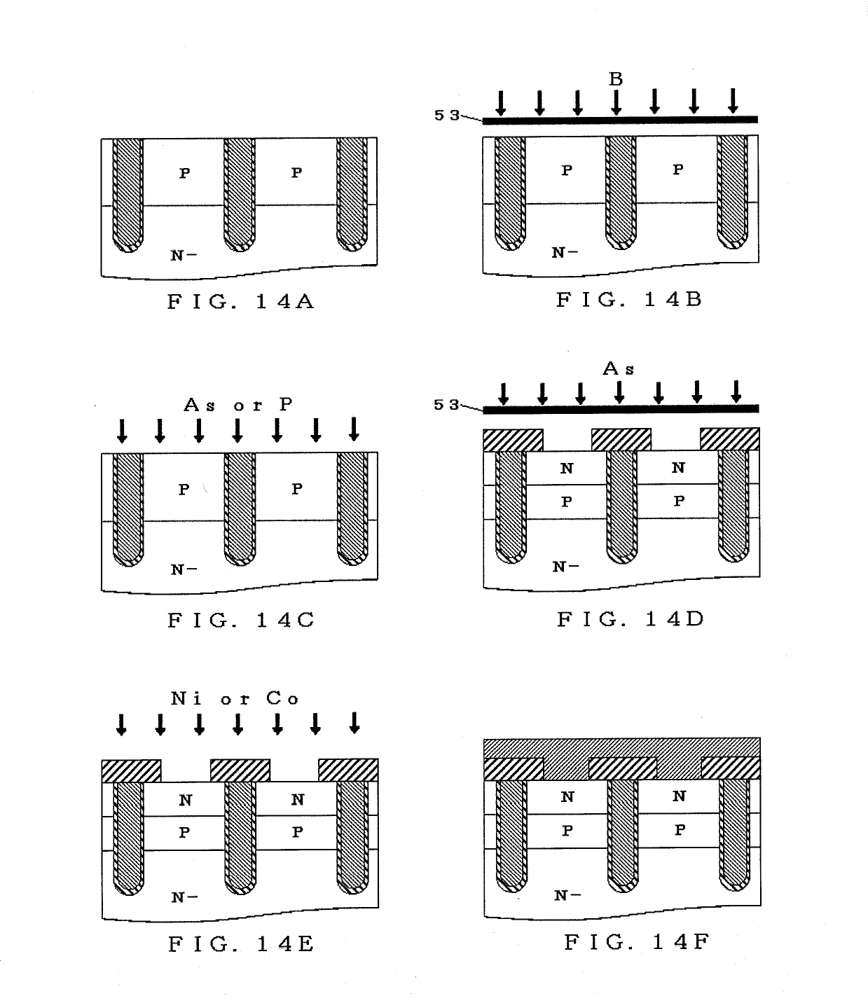

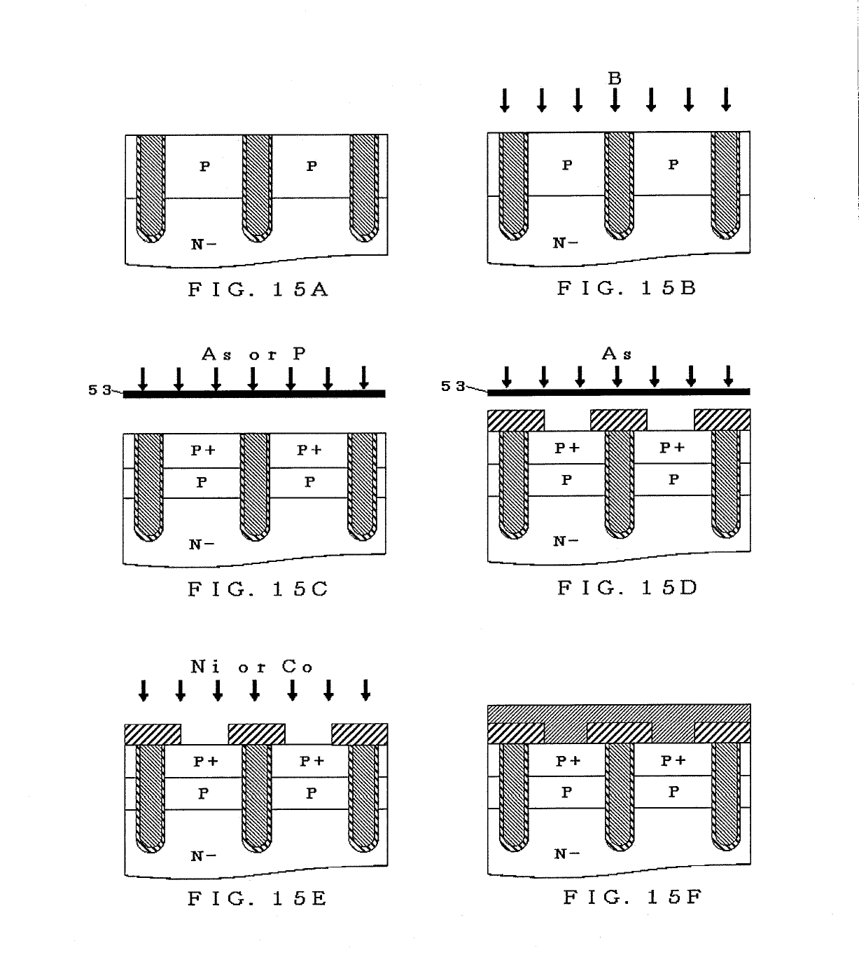

Now, formation processes for selectively providing the N⁺-type emitter layer 21 by means of As segregation using nitrogen silicide (NiSi), for example, will be described below with reference to FIG. 13A to FIG. 15F. FIG. 13A to FIG. 13F are cross-sectional views taken along the G-G′ line in FIG. 11, showing a sequence of processes. FIG. 14A to FIG. 14F are cross-sectional views taken along the H-H′ line in FIG. 11, showing the sequence of processes. FIG. 15A to FIG. 15F are cross-sectional views taken along the I-I′ line in FIG. 11, showing the sequence of processes. In FIG. 13A to FIG. 15F, the processes sequentially take place in the order of from part A to part F.

### (First Step)

FIGS. 13A, 14A, and 15A show the cross-sectional views of respective portions after the N⁻-type base layer 10, the P-type base layer 11, the trenches 12, the gate insulating film 13, and the gate electrodes 14 are formed in the substrate 2. Thereafter, in order to form the P⁺-type contact layer 16, boron (B) is ion-implanted into the P-type base layer 11 as shown in FIG. 15B by means of lithography technology. As shown in FIG. 13B or FIG. 14B, a mask 53 is provided above portions where the N-type emitter layer 15 or the N⁺-type emitter layer 21 is supposed to be formed. In this way, ion implantation into such portions is avoided. Although boron (B) is cited as an example of P-type ionic species, the ionic species is not limited only to boron as long as other ionic species can successfully form the P⁺-type contact layer 16.

### (Second Step)

FIGS. 13C, 14C, and 15C show a process of forming the N-type emitter layer 15 having the low surface impurity concentration on the P-type base layer 11. As shown in FIGS. 13C and 14C, either phosphorus (P) or arsenic (As) is ion-implanted into the P-type base layer 11 in order to form the N-type emitter layer 15. Here, the surface impurity concentration of phosphorus (P) or arsenic (As) is adjusted equal to or less 1×10¹⁹ cm⁻³. Meanwhile, as shown in FIG. 15C, phosphorus (P) or arsenic (As) is not implanted into the P⁺-type contact layer 16 by means of providing the mask 53. Although phosphorus (P) and arsenic (As) are cited as examples of N-type ionic species, the ionic species is not limited only to phosphorus and arsenic as long as other ionic species can successfully form the N-type emitter layer 15.

Then, annealing is performed in order to activate the impurities and the insulating film 17 is thus formed on the gate electrodes 14. Thereafter, only part of the insulating film 17 located at the portions of contact (the contact regions 50) with the emitter layer 18 is removed by etching.

### (Third Step)

FIGS. 13D, 14D, and 15D show a process of selectively ion-implanting arsenic (As) at a low acceleration voltage in order to form the N⁺-type emitter layers 21 partially in the N-type emitter layer 15. As shown in FIG. 13D, arsenic (As) is ion-implanted at a low acceleration voltage into the portions to be formed into the N⁺-type emitter layers 21. Meanwhile, as shown in FIGS. 14D and 15D, arsenic (As) is not implanted into portions where the formation of the N⁺-type emitter layer 21 is not intended by means of providing the mask 53. Thereafter, the impurity is activated by rapid thermal annealing (RTA).

### (Fourth Step)

FIGS. 13E, 14E, and 15E show a process of sputtering nickel (Ni) or cobalt (Co) in order to form the N⁺-type emitter layers 21 partially in the N-type emitter layer 15. As shown in FIGS. 13E, 14E, and 15E, either Ni or Co is sputtered onto the entire surface.

### (Fifth Step)

Then, Ni or Co is transformed into a silicide by performing RTA or the like. This process promotes segregation of As in an interface of nickel silicide (NiSi) or cobalt silicide (CoSi), whereby the N⁺-type emitter layers 21 are formed only at the portions where As is ion-implanted at the low acceleration voltage. Thereafter, as shown in FIGS. 13F, 14F, and 15F, the emitter electrode 18 is formed by using aluminum (Al) or the like.

The semiconductor device 1 of the second embodiment shown in FIG. 11 or FIG. 12 is formed by the above-described processes.

### Third Embodiment

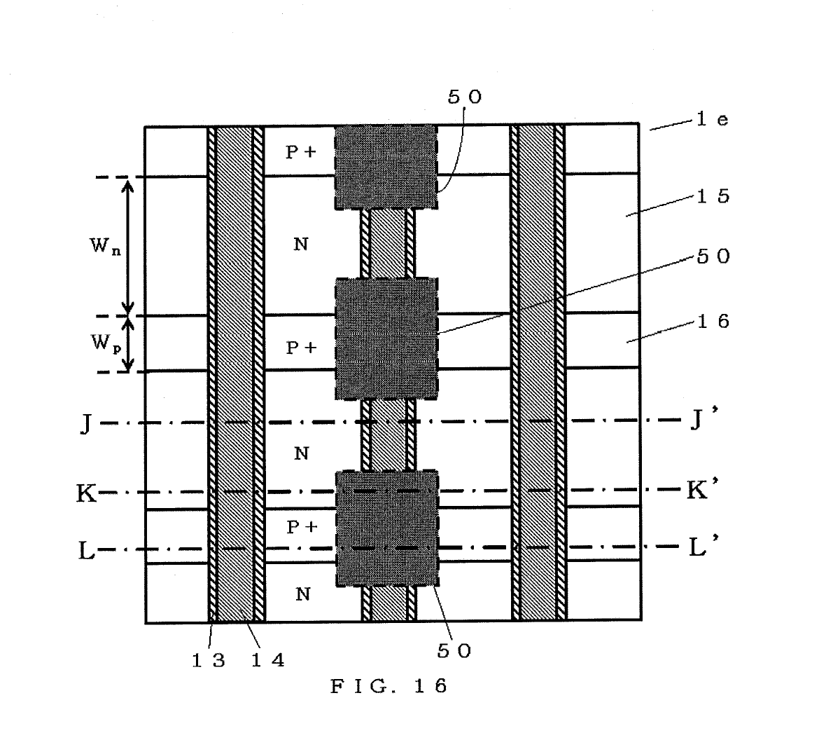

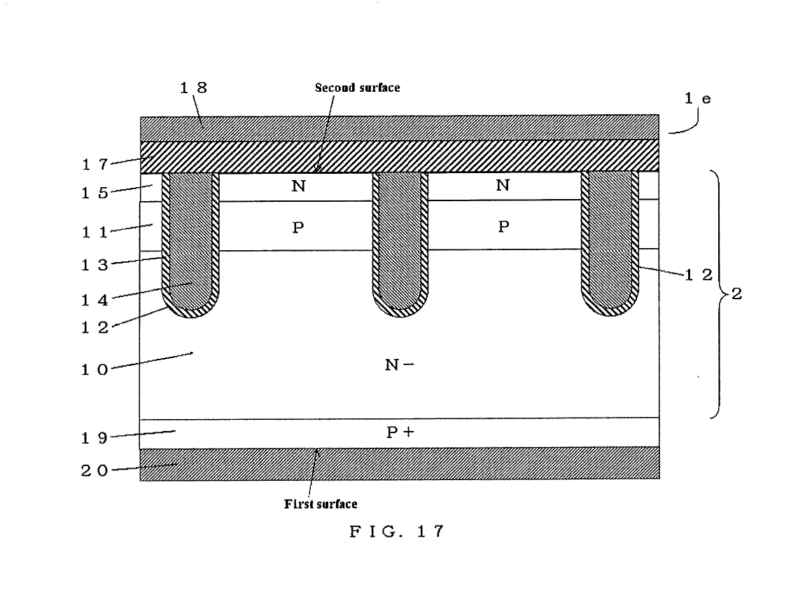

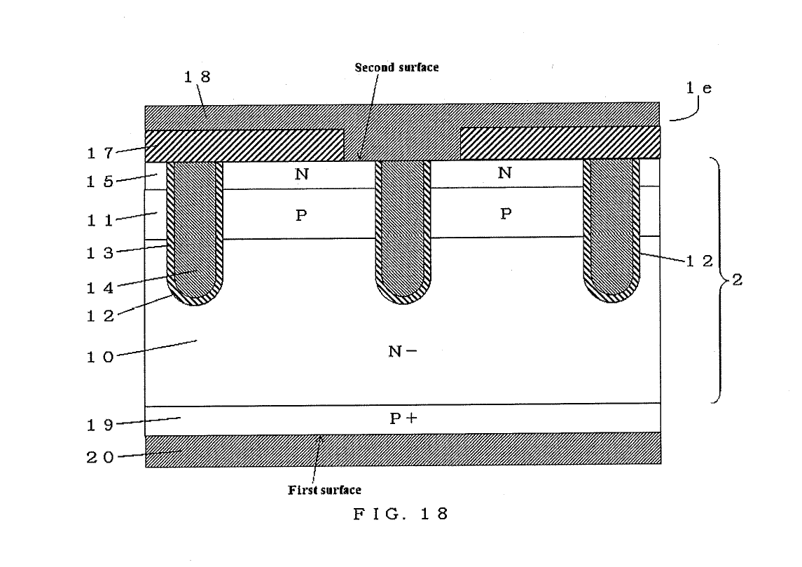

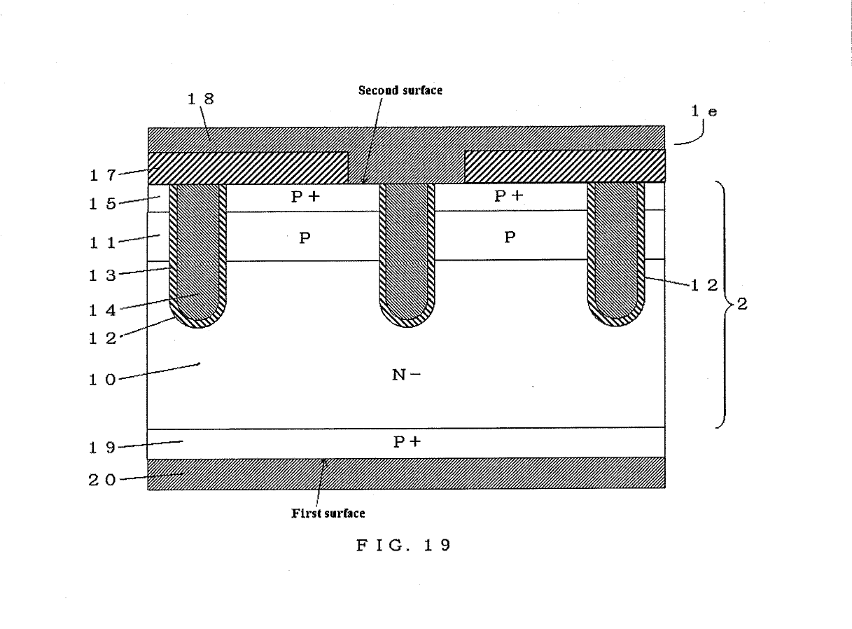

FIG. 16 is a plan view showing a semiconductor device of a third embodiment, FIG. 17 is a cross-sectional view showing a cross section taken along the J-J′ line in FIG. 16, FIG. 18 is a cross-sectional view showing a cross section taken along the K-K′ line in FIG. 16, and FIG. 19 is a cross-sectional view showing a cross section taken along the L-L′ line in FIG. 16. Here, illustration of the insulating film 17 and the emitter electrode 18 is omitted in FIG. 16. It is to be also noted that the constituents in the third embodiment which are the same as the constituents of the semiconductor device 1 of the first embodiment shown in FIG. 1 and FIG. 2 will be denoted by the same reference numerals.

The semiconductor device 1 of the third embodiment is different from the semiconductor device of the first embodiment in that the portion of contact between the N-type emitter layer 15 and the emitter electrode 18 is formed on the trenches 12 (the gate insulating film 13 and the gate electrodes 14). That is, a part of the gate electrodes 14 is connected to the emitter electrode 18 in the trenches 12.

An effect of the third embodiment is an increase of IE effect occurred by the trenches 12 close to each other and an area of the N-type emitter layer 15 is more smaller than an area of the P⁺-type contact layer 16 at a plan view of the semiconductor device 1. However, the trenches 12 close rapidly to each other, and it is possible that contact regions 50 are inadequate.

In the semiconductor device 1 of the third embodiment, it is easy to form adequately contact regions 50 by forming contact regions 50 on the trenches 12. Thus, it is possible that the trenches 12 close to each other, and IE effect increase. That is, hole density accumulated in the N⁻-type base layer 10 near bottom of the trenches 12 increase, it is possible to improve trade-off between switching loss and on-voltage at off-time.

In addition, the amount of the gate electrodes 14 forming in the trenches 18 decrease virtually by a part of the gate electrode 14 is connected to the emitter electrode 18 and become emitter electric potential. That is, a gate capacity of the semiconductor device 1 decreases. Thus, a drive current of the semiconductor device 1 decrease and it is possible to diminish a driver circuit.

As it is for the first and second embodiments, the semiconductor device 1 of the third embodiment can reduce the on-voltage and ensure the short-circuit capacity at the same time by setting the ratio Wₙ/Wₚ between the width Wₙ of the N-type emitter layer 15 having a lower surface impurity concentration than the conventional layer and the width Wₚ of the P⁺-type contact layer 16 equal to or more 0.6 or preferably equal to or more 1, and by providing the non-contact portion by partially reducing the portion of contact between the N-type emitter layer 15 and the emitter electrode 18 with formation of the insulating film 17.

In the third embodiment, the trenches 12 close to each other less than 1 μm, for example. And the amount of the gate electrode 14 connected to the emitter electrode 18 don't confine except all gate electrode 14 connected to the emitter electrode 18.

Although a structure of an element terminal is not particularly discussed herein, it is possible to realize any types of terminal structures including a field plate structure, a reduced surface field (RESURF) structure, a guard ring structure, and the like without causing adverse effects.

Silicon (Si) can be used as the semiconductor, for example. However, the semiconductor is not limited only to silicon and the invention can also be embodied by using a compound semiconductor such as silicon carbide (SiC) and gallium nitride (GaN), or a wide gap semiconductor such as diamond.

Moreover, the method of forming the semiconductor device 1 is not limited only to the ion implantation method, and the semiconductor device 1 can also be formed in accordance with an epitaxial method or a combination of the ion implantation method and the epitaxial method, for example. When the semiconductor device 1 is formed in accordance with the epitaxial method, the N⁻-type base layer 10 serves as the substrate 2, for example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first-conductive-type base layer provided in a substrate having first and second surfaces;
a second-conductive-type collector layer provided on the first surface;
a collector electrode provided on the second-conductive-type collector layer;
a second-conductive-type base layer provided on the second surface;
a second-conductive-type contact layer selectively provided on the second-conductive-type base layer;
trenches provided on the on a side of second surface;
a gate electrode provided in each of the trenches via a gate insulating film;
a first-conductive-type emitter layer provided on the trenches;
an insulating film provided on the gate electrodes; and
an emitter electrode provided on the second surface, and having a non-contact portion partially provided in the first-conductive-type emitter layer.

2. The semiconductor device of claim 1, wherein a surface impurity concentration of the first-conductive-type emitter layer is equal to or more 1×10¹⁸ cm⁻³ and less 5×10¹⁹ cm⁻³.

3. The semiconductor device of claim 1, wherein, in a longitudinal direction of the trenches, a ratio of a width of the first-conductive-type emitter layer to a width of the second-conductive-type contact layer is equal to or more 0.6.

4. The semiconductor device of claim 1, wherein a part of the gate electrode contacts emitter electrode.

5. A semiconductor device comprising:
a first-conductive-type base layer provided in a substrate having first and second surfaces;
a second-conductive-type collector layer provided on the first surface;
a collector electrode provided on the second-conductive-type collector layer;
a second-conductive-type base layer provided on the second surface;
a second-conductive-type contact layer selectively provided on the second-conductive-type base layer;
trenches provided on a side of the second surface;
a gate electrode provided in each of the trenches via a gate insulating film;
a first-conductive-type emitter layer provided on the trenches;
an insulating film provided on the gate electrodes; and
an emitter electrode provided on the second surface, and having a portion in ohmic contact and a portion in Schottky contact with the first-conductive-type emitter layer.

6. The semiconductor device of claim 5, wherein
a surface impurity concentration of the portion of the first-conductive-type emitter layer in ohmic contact with the emitter electrode is equal to or more 1×10¹⁹ cm⁻³, and
a surface impurity concentration of the portion of the first-conductive-type emitter layer in Schottky contact with the emitter electrode is less 1×10¹⁹ cm⁻³.

7. The semiconductor device of claim 5, wherein the portion of the first-conductive-type emitter layer is brought into ohmic contact with the emitter electrode by arsenic segregation caused at the portion of the first-conductive-type emitter layer.

8. The semiconductor device of claim 5, wherein, in the longitudinal direction of the trenches, a ratio of a width of the first-conductive-type emitter layer to a width of the second-conductive-type contact layer is equal to or more 0.6.

9. The semiconductor device of claim 5, wherein a portion of the gate electrode contacts the emitter electrode.
